(19) United States
(12) Patent Application Publication
(10) Pub. No.: US 2025/0336886 A1
(43) Pub. Date: Oct. 30, 2025

(54) INTEGRATED CIRCUIT (IC) WITH EXPOSED ACTIVE CIRCUITRY

(71) Applicant: TEXAS INSTRUMENTS INCORPORATED, DALLAS, TX (US)

(72) Inventors: Anindya PODDAR, SUNNYVALE, CA (US); Mahmud CHOWDHURY, PLANO, TX (US)

(21) Appl. No.: 18/651,057

(22) Filed: Apr. 30, 2024

(51) Int. Cl. H01L 23/00; H01L 21/56; H01L 23/31

(52) U.S. Cl. CPC H01L 24/94; H01L 21/565; H01L 23/3185; H01L 24/13; H01L 24/16; H01L 24/29; H01L 24/32; H01L 24/33; H01L 24/48; H01L 24/73; H01L 2224/1319; H01L 2224/13191; H01L 2224/16221; H01L 2224/16225; H01L 2224/2919; H01L 2224/29191; H01L 2224/32221; H01L 2224/32225; H01L 2224/32245; H01L 2224/3303; H01L 2224/33181; H01L 2224/48091; H01L 2224/48245; H01L 2224/73215; H01L 2224/94; H01L 2924/0665; H01L 2924/07025; H01L 2924/0715

(57) ABSTRACT

In one example, a method can include forming a mask layer on a first surface of a first wafer, forming a pattern in the mask layer to expose areas of the first wafer through the mask layer, and removing a substrate layer from the first wafer from the exposed areas of the first surface of the first wafer to expose a second layer of the first wafer or to expose dies. In another example, a method can include providing a cap over an area on a surface of a die bonded to and spaced apart from the surface of the die by a spacer, applying mold compound to encapsulate the die and at least a portion of the cap such that a surface of the cap remains unencapsulated, and removing at least a portion of a layer from the cap over the area of the die.

### TECHNICAL FIELD

This description relates generally to electrical devices, and more particularly to a design for an exposed active circuitry integrated circuit (IC) package.

### BACKGROUND

Integrated circuits (ICs) are formed on a single die, or “chip,” and singulated from a semiconductor wafer containing a number of identical dies. The dies are mounted to leadless or leaded carrier, also referred to as a leadframe, and packaged in molding compound to protect them from the environment.

### SUMMARY

In a described example, a method can include forming a mask layer on a first surface of a first wafer. The first wafer has a second surface that is opposite the first surface. The first wafer can include a substrate layer and a second layer between first and second surfaces thereof. The second surface of the first wafer is bonded to a surface of a second wafer by a die attach material that spaces the second surface of the first wafer apart from the surface of the second wafer. The second wafer can include a plurality of dies distributed across the surface of the second wafer. Each die includes active circuitry on the at locations on the surface of the second wafer spaced from the die attach material. The method can include forming a pattern in the mask layer to expose areas on the first surface of the first wafer through the patterned mask layer, wherein the exposed areas overlie respective active circuitry of the second wafer and removing the substrate layer from the first wafer from the exposed areas of the first surface of the first wafer to provide openings that overlie respective active circuitry.

In a described example, a method can include providing a cap overlying an area on a first surface of a die, in which the cap includes a first layer over a second layer between opposing first and second surfaces, the second surface of the cap is bonded to and spaced apart from the first surface of the die by a spacer, and an area of the die spaced inwardly from the spacer includes active circuitry, applying mold compound to cover the die and at least a portion of the cap such that the first surface of the cap is uncovered, and removing at least a portion of the first layer from the cap that overlies the area of the die to form an opening, the opening extends from the first surface of the first structure through the substrate layer and is aligned with an area at the surface of the second structure occupied by the active circuitry.

In a described example, an apparatus can include a first structure, a second structure, and an opening. The first structure can include a substrate layer on an oxide layer, the first structure having a first surface that is opposite a second surface. The second structure is bonded to the second surface of the first structure by die attach material that spaces the second surface of the first structure from a surface of the second structure. The second structure includes an active circuitry at the surface of the second structure at a location spaced inwardly from the die attach material. The opening in the first structure exposes the oxide layer of the first structure or exposes the active circuitry.

In a described example, an apparatus can include a die, a spacer, and mold compound. The die can include active circuitry positioned at an area at or near a surface of the die. The spacer is disposed on the surface of the die, the area containing the active circuitry being spaced inwardly from the spacer. The mold compound covers at least a portion of the die. The active circuitry or a translucent or transparent layer of material on the active circuitry is uncovered. An inner sidewall surface of the mold compound extending from the surface of the die or an inner sidewall surface associated with the uncovered portion extending from the surface of the die is orthogonal to the surface of the die.

### BRIEF DESCRIPTION OF THE DRAWINGS

FIG. 1 is a flow diagram of an example method for manufacturing an integrated circuit (IC) having exposed active circuitry.

FIGS. 2-14 are diagrams of examples of process flows for manufacturing an integrated circuit (IC) having exposed active circuitry.

FIG. 15 is a flow diagram of an example method for manufacturing an integrated circuit (IC) having exposed active circuitry.

FIGS. 16-23 are diagrams of examples of process flows for manufacturing an integrated circuit (IC) having exposed active circuitry.

### DETAILED DESCRIPTION

This description relates to an exposed active circuitry integrated circuit (IC) package including single- or multi-chip packages, system in a package (SiP), and/or a system on a chip (SoC), in which active circuitry of a die or one or more portions thereof are exposed at a respective surface of the die. It is advantageous for certain types of sensors to be exposed (e.g., to the ambient environment). For example, humidity sensors or ambient light sensors can benefit from having active circuitry of the die being exposed. While custom cavity molds and wall-based cavity structures can expose active circuitry in a packaged IC, these tend to come at the expense of increased cost and modified process flows. The exposed active circuitry IC packages described herein can leverage wafer level encapsulation (WLE) to provide a cavity to expose active circuitry of a die for a package, such as a quad-flat no lead (QFN) package, for example.

According to one example, a first wafer is bonded onto and spaced away from a second wafer and the first wafer functions as a cap for the die, which is located on the second wafer (e.g., using WLE). The first wafer includes a substrate layer on an oxide layer. A mask layer is formed on the substrate layer and patterned such that the substrate layer can be etched, down to the oxide layer, to form the desired cavity. Thereafter, the oxide layer can be removed, thereby exposing the active circuitry of the die of the IC. Film assisted molding (FAM) can be utilized to package the IC. For example, a film can be applied to a mold chase using vacuum sealing. The IC can be loaded into the mold chase and the mold can be closed. Cavities within the mold chase are filled with mold compound such that the mold compound does not enter the cavity because mold chase clamping and sealing around an opening of the cavity during encapsulation are adapted to prevent the mold compound from entering the cavity. FAM helps this to occur more easily and potentially at lower clamping forces.

According to another example, a cap is bonded onto and spaced away from a die (e.g., at package level). Thereafter, mold compound is applied to cover (e.g., encapsulate) the die and at least a portion of the cap such that a surface of the cap is uncovered (e.g., unencapsulated) by mold compound and at least a portion of a layer from the cap overlying the area of the die is removed to expose the active circuitry or a layer on the die of the IC. In this way, a low-cost solution using existing package processes, such as WLE, is provided while avoiding expensive mold tooling or modifying manufacturing process flows.

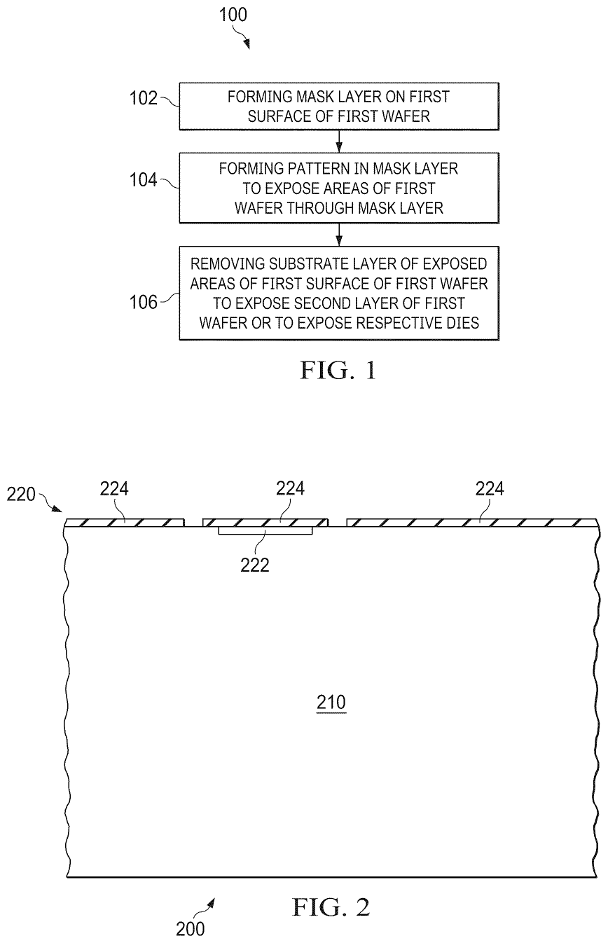

FIG. 1 is a flow diagram of an example method 100 for backend processing for packaging an integrated circuit (IC) having exposed active circuitry at a surface of a die of the IC. As described herein, the IC being packaged can include one or more dies of an assembly, which can be attached to a leadframe and include bond wires making respective interconnections within the package. FIG. 1 is described with reference to FIGS. 2-14, which are diagrams of examples at various stages of a manufacturing process flow for manufacturing and packaging the IC having the exposed active circuitry.

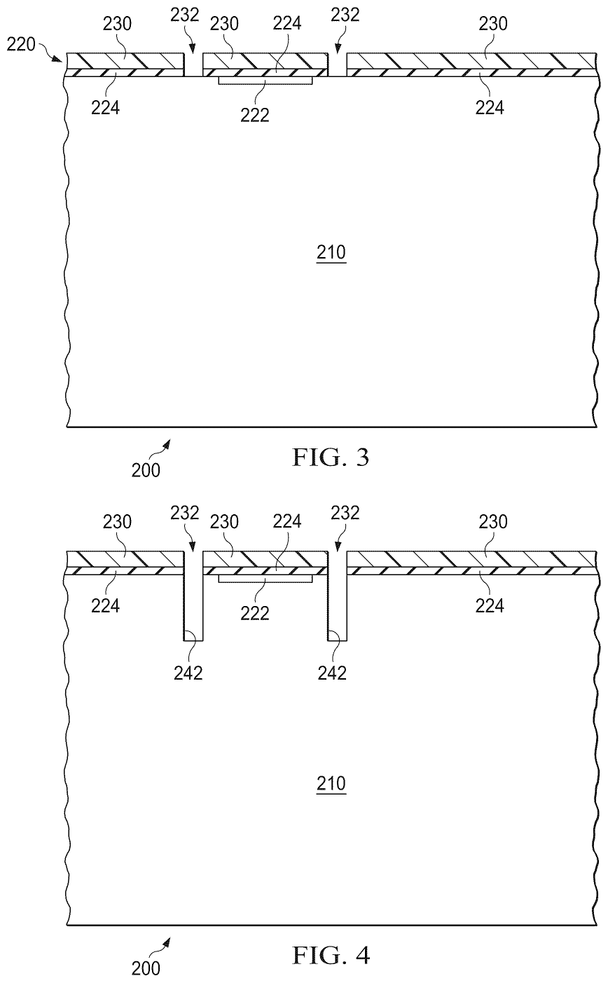

For example, with reference to FIG. 2, a wafer 200 is provided with a substrate layer 210 and a second layer 220 on the substrate layer 210. The second layer 220 can include a number of active circuitry 222 and protective material 224, such as a layer of a protective oxide or silicon dioxide (SiO₂). In the following examples, each of the active circuitry 222 includes one or more ICs that have been fabricated in the substrate layer 210 of the wafer 200 or, in some examples, also on the layer 220. As described herein, each IC can be configured to perform one or more functions (e.g., sensing function) according to a particular purpose or use environment. With reference to FIG. 3, a mask layer 230 is formed and patterned on a surface of the second layer 220 (e.g., by photolithography) to provide openings 232 spaced from the active circuitry 222. For example, the mask layer can be a photoresist material that has been patterned and etched to provide the openings 232, such as shown. As shown in FIG. 4, trenches 242 are formed (e.g., by etching) in the substrate layer 210 around the active circuitry 222, such as through the openings in the mask layer 230. In FIG. 5, the mask layer 230 is removed, such as by chemical stripping with a solvent. Thus, the wafer 200 has a first surface 552 that is opposite a second surface 554.

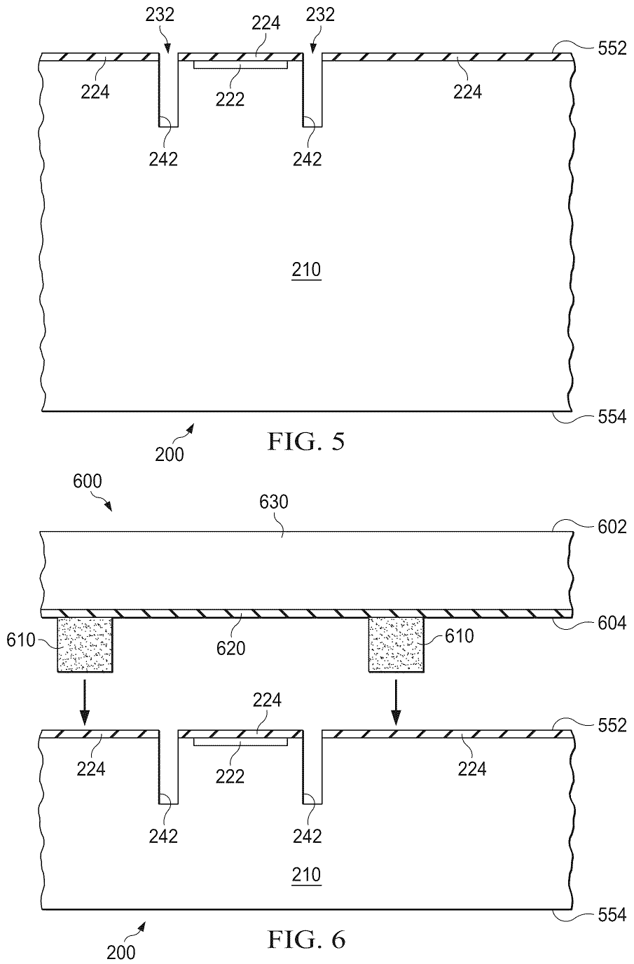

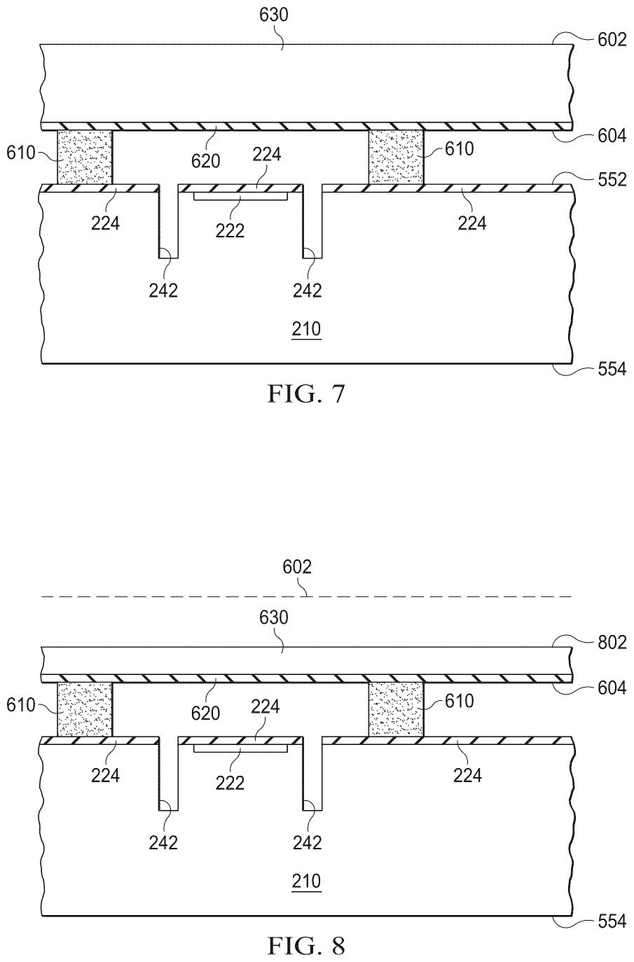

FIGS. 6-7 show a wafer level encapsulation (WLE), in which another wafer 600 is being bonded to the wafer 200 from FIG. 5. The wafer 600 can be another semiconductor wafer, such as crystalline silicon. In an example, the wafer 600 is used to form respective caps for a plurality of IC die and thus do not include active circuitry. Accordingly, rejected (e.g., defective) silicon wafers can be used as the wafer 600 in the method 100. The wafer 600 has first and second opposing surfaces 602 and 604. For example, the wafer 600 includes substrate layer 630 and a second layer, such as an oxide layer 620 (e.g., including silicon dioxide (SiO₂), is on the substrate layer to define the second surface 604. For example, the first layer is a substrate layer 630 and the second layer is an oxide layer 620). As seen in FIG. 7, the second surface 604 of the wafer 600 is bonded to the first surface 552 of the wafer 200 by die attach material 610 (e.g., epoxy, polyimide, benzocyclobutene (BCB), silicone, solder, or other adhesive) that spaces the second surface 604 of the wafer 600 from the first surface 552 of the wafer 200. Additionally, the die(s) 222 are at or adjacent to the first surface 552 of the wafer 200 and spaced inwardly from the die attach material 610.

It will be appreciated that thicknesses of one or more of the layers described herein can be adjusted, such as by WLE backgrinding, to remove material from the corresponding layer. For example, a portion of the substrate layer 630 of the wafer 600 can be removed from the first surface 602 by WLE backgrinding down to provide a different surface 802, as shown in FIG. 8.

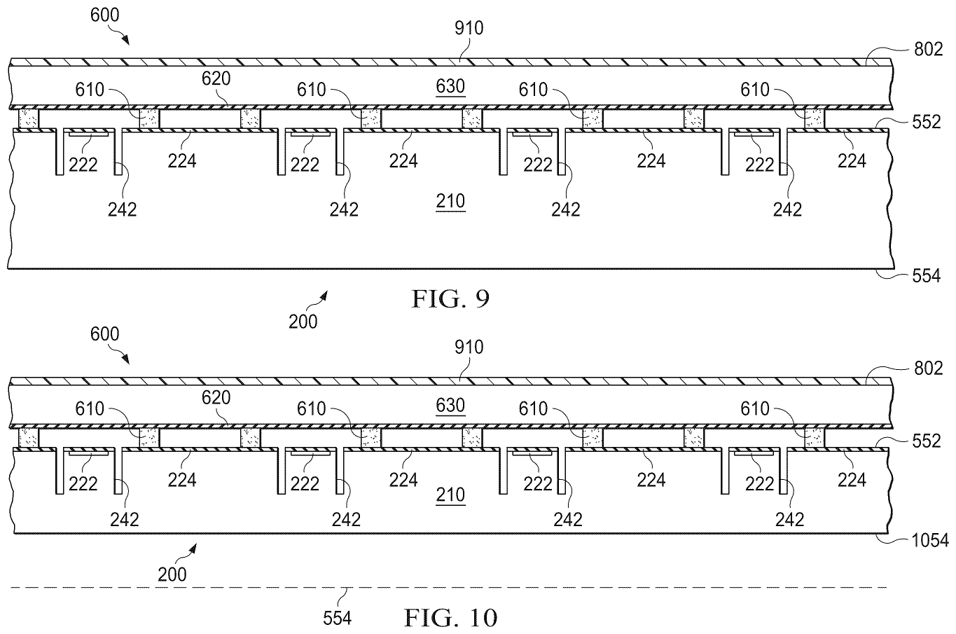

As shown in FIG. 9, the wafer 200 can include a plurality of active circuitry 222 distributed across the first surface 552 of the wafer 200 at locations spaced from the die attach material 610, which acts as a standoff to space apart the opposing surfaces of the wafers 600 and 200. The method 100 can include forming 102 a mask layer 910 on the first surface 802 of the wafer 600, such as by spin coating a layer of photoresist on the first surface 802 of the wafer 600. In FIG. 10, a portion of the substrate layer 210 of the wafer 200 can be removed from the second surface 554 (e.g., by WLE backgrinding) down to provide the wafer 200 a different surface 1054.

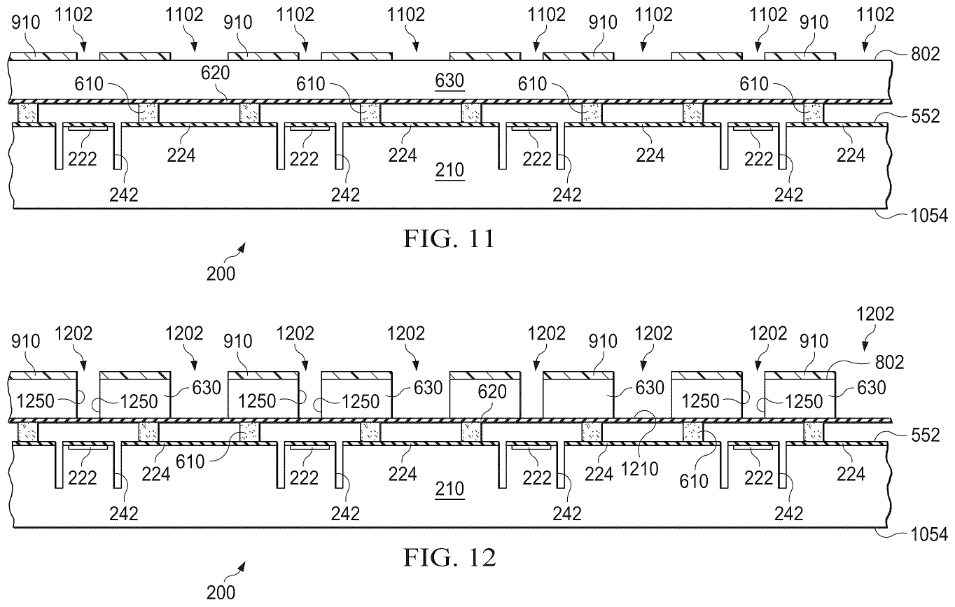

As seen in FIG. 11, the method 100 can include forming 104 a pattern in the mask layer 910 to expose areas 1102 of the wafer 600 (e.g., the substrate layer 630) through the mask layer 910. At least some of the exposed areas 1102 can overlie (e.g., axially aligned with) respective active circuitry 222 or are otherwise positioned above (e.g., in an overlying spatial position relative to) the respective active circuitry 222.

Returning to FIG. 1, at 106, the method 100 can include removing a substrate layer from exposed areas of the first surface of a first wafer to expose second layer of the first wafer or to expose respective active circuitry of a die. According to one example, with reference to FIG. 12, the at least a portion of the substrate layer 630 can be removed from the wafer 600 from the exposed areas 1102 of the first surface 802 of wafer 600 to expose a surface 1210 of the second layer (e.g., the oxide layer 620) of the wafer 600 and create openings 1202. For example, the removing of the portion of the substrate layer 630 at 106 can be achieved by plasma etching the substrate layer 630 down to the oxide layer 620 to define respective vertical sidewalls 1250 of an aperture in the substrate layer 630 around the openings 1202. The sidewalls 1250 can define cylindrical sidewalls that extend at least between surfaces 802 and 1210 of the wafer 600. The sidewalls 1250 of the opening can extend orthogonally with respect to the surfaces 802 and 604 of the wafer 600. The sidewalls 1250 of the opening can also extend orthogonally with respect to the surface 552 of the wafer 200 and with respect to the surface of the die containing the active circuitry 222. In this way, wafer level encapsulation (WLE) provides a process flow which enables the fabrication of an exposed active circuitry IC package with minimal package mold stress.

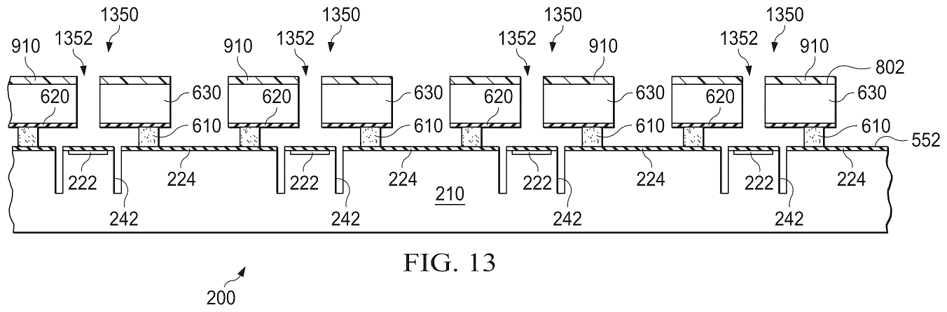

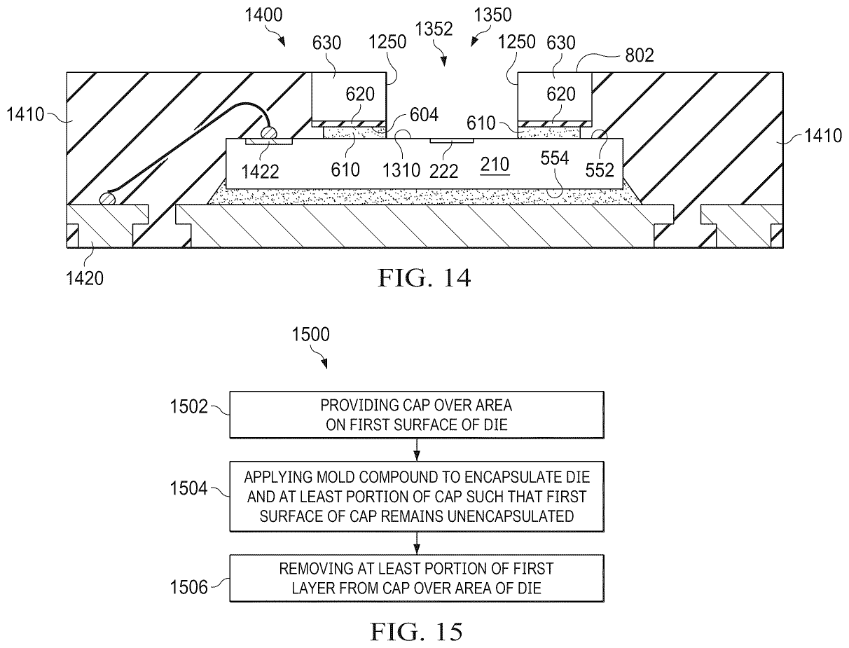

According to another example, with reference to FIGS. 1 and 13, at 106, the method 100 can include removing both the substrate layer 630 and the oxide layer 620 from the exposed areas 1102 to expose the respective active circuitry 222 therethrough. In some examples, a layer of protective oxide 224 can be on the surface of the wafer over the active circuitry 222 or, alternatively, it can be removed wholly or partially. For example, after removing the substrate layer 630 (e.g., by plasma etching), which leaves the oxide layer 620 intact, a waterjet can be applied onto the wafer 600 and into the openings 1202 to break the exposed portions of the oxide layer 620 within the sidewalls 1250 and define an opening (e.g., aperture) 1352 extending completely through the wafer 600 over the respective instances of the active circuitry 222 on the wafer 200. Thereafter, each IC 1350 can be singulated and packaged to provide a packaged IC apparatus 1400, such as shown in FIG. 14. Film assisted molding (FAM) can be implemented for packaging. For example, a film can be applied to a mold chase using vacuum sealing. The IC 1350 can be loaded into the mold chase and the mold can be closed. Cavities within the mold chase are filled with mold compound. The mold compound does not enter the cavity since mold chase clamping and sealing around the opening during encapsulation prevents the mold compound from entering the cavity.

As shown in the example FIG. 14, a packaged IC apparatus 1400 can be formed with an exposed active circuitry 222. The packaged IC apparatus 1400 can include a first structure (e.g., corresponding to a portion of the wafer 600), a second structure (e.g., corresponding to a portion of the wafer 200), and an opening 1352 in the first structure. Again, the sidewalls 1250 are orthogonal with respect to the surface 552 the active circuitry 222. The first structure can include the substrate layer 630 on the oxide layer 620. The second structure is bonded to the second surface 604 of the first structure by the die attach material 610 that spaces the second surface 604 of the first structure from the first surface 552 of the second structure. The second structure can include the active circuitry 222 positioned at a location spaced from the die attach material 610. The active circuitry 222 is at or adjacent to the surface of the second structure. The opening 1352 in the first structure is configured to expose the oxide layer 620 of the first structure or to expose a surface overlying the active circuitry 222. For example, the opening 1352 extends from the surface 802 of the first structure through the substrate layer 630 and is aligned with an area at the surface 552 of the second structure overlying the active circuitry 222.

According to one example, film assisted molding (FAM) can be implemented to form mold compound 1410 around the IC. Mold chase clamping and sealing prevents the mold compound 1410 from entering the opening 1352. The mold compound 1410 thus encapsulates the portions of the respective wafers 200 and 600 but leaves the opening unencapsulated to expose the surface overlying the active circuitry 222 through the opening 1352 to provide the packaged IC apparatus 1400. The packaged IC apparatus 1400 can include a leadframe 1420 coupled to a bond pad 1422 near the surface 554 of the wafer 200.

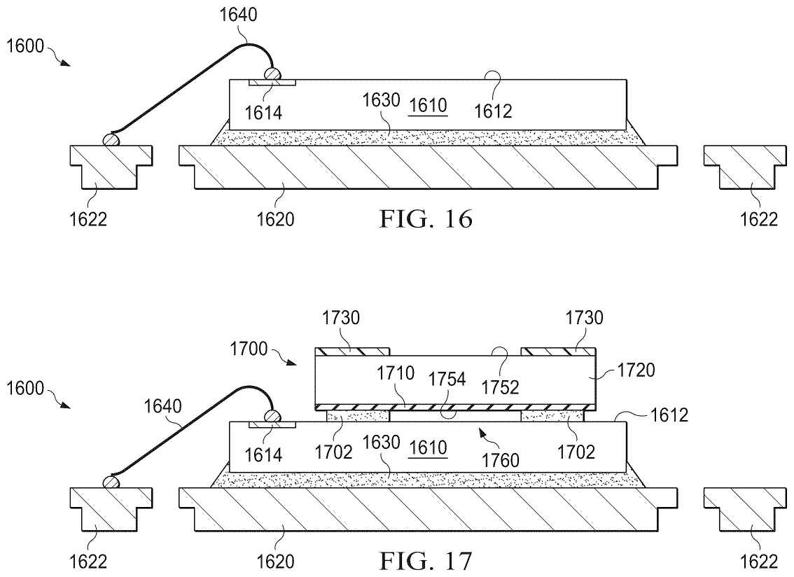

FIG. 15 is a flow diagram of an example method 1500 for manufacturing an IC having exposed active circuitry. FIG. 15 is described with reference to FIGS. 16-23, which are diagrams of examples at various stages of a process flow for manufacturing the IC having the exposed active circuitry.

According to one example, each IC from any of FIGS. 7-11 can be singulated from the composite structure of wafers 200 and 600 to provide a structure 1600 shown in FIG. 16. The structure includes a die 1610 mounted on a leadframe 1620 by an adhesive 1630. The die 1610 can have a surface 1612 that includes one or more bond pads 1614 is coupled to a pad on leadframe 1622 by way of a bond wire 1640.

Returning to FIG. 15, at 1502, the method 1500 can include providing on or over an area on the surface of the die, a cap on or overlying an area on the surface of the die. As shown in the example of FIG. 17, a cap 1700 is on or overlying an area on the surface 1612 of the die 1610. The cap 1700 includes a first layer 1720 over a second layer 1710 between opposing first and second surfaces 1752, 1754. For example, the first layer 1720 is a substrate layer, such as a silicon substrate, and the second layer 1710 is an oxide layer. A mask layer 1730 of a photoresist material can be formed and patterned on the first layer 1720, such as shown in FIG. 17. The second surface 1754 of the cap 1700 is bonded to and spaced apart from the surface 1612 of the die 1610 by a spacer 1702. The spacers 1702 have a thickness to define a spacing between adjacent surfaces of the cap 1700 and die surface 1612. The spacers 1702 also have inner and outer peripheries spaced apart from each other to define a size of an opening over the die 1610. The inner periphery of the spacers 1702 is spaced apart from and surrounds the active circuitry 1760 on the die. An area of the die 1610 spaced inwardly from the spacers 1702 includes active circuitry 1760, such as including one or more sensors. Further, the spacers 1702 can include one or more layers of material (e.g., die attach material) between the cap 1700 and the surface 1612 of the die 1610.

At 1504, the method 1500 can include applying mold compound to encapsulate the die and at least a portion of the cap such that the first surface of the cap is unencapsulated. For example, FIG. 18 shows a mold compound 1810 applied to encapsulate the die 1610 and at least a portion of the cap 1700 and leadframe 1622. The mold compound 1810 can be applied such that the first surface 1752 of the cap 1700 is unencapsulated, as seen in FIG. 18. For example, the mold compound 1810 can be applied with mold chases and with film assisted molding (FAM). The mold chase can be arranged and configured to clamp onto the first surface of the 1752 of the cap 1700 so a corresponding surface within the mold chase seals around the cap and causes the mold compound 1810 to not extend onto the first surface 1752 of the cap 1700.

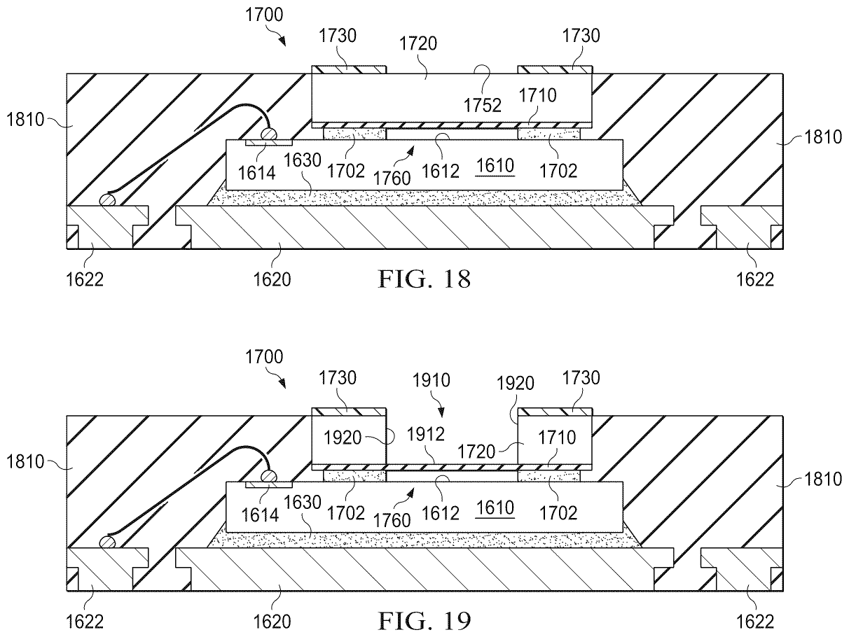

At 1506, the method 1500 can include removing at least a portion of the first layer 1720 from the cap 1700 that extends over an area of the die, such as an area associated with the active circuitry 1760 between the spacers 1702. With reference to FIG. 19, for example, the first layer 1720 is removed to form an opening 1910 that resides over a surface area 1912 of the second layer 1710 (e.g., the oxide layer). In this way, the structure or apparatus of FIG. 19 can include the die 1610, the spacers 1702 on the surface 1612 of the die 1610, the active circuitry 1760 positioned at an area of the die 1610 spaced inwardly from the spacers 1702, and mold compound 1810. As described herein, one or more sensors can be provided on the area of the die spaced inwardly from the spacers 1702. The mold compound 1810 encapsulates at least a portion of the die 1610 such that the active circuitry 1760 or a translucent or transparent layer of material (e.g., second layer 1710, such as an oxide layer) on the active circuitry 1760 is unencapsulated and a surface 1920 of the mold compound 1810 or a surface associated with the unencapsulated portion is orthogonal to the surface 1612 of the die 1610. For example, surface 1920 is an inner sidewall surface of the unencapsulated portion which extends from the surface 1612 of the die and is orthogonal to the surface 1612 of the die.

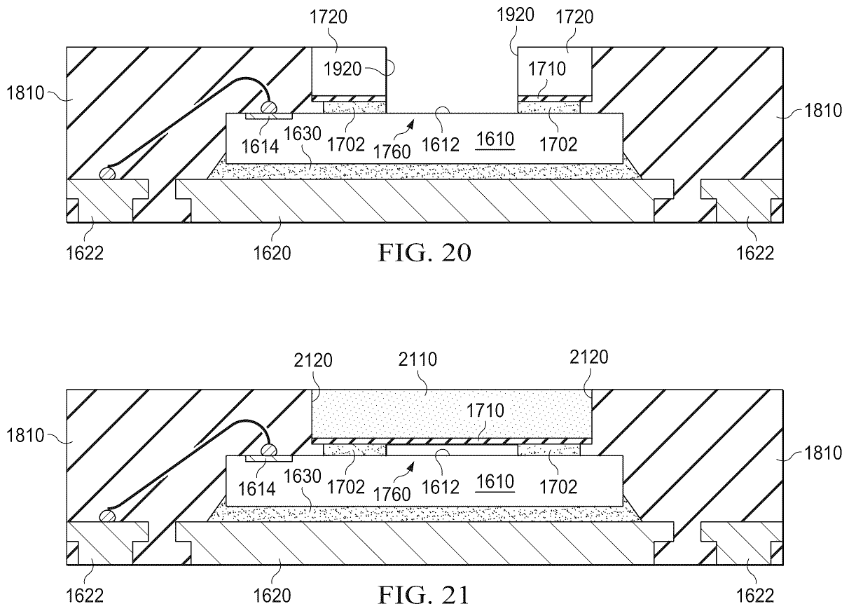

FIGS. 20-23 are different example embodiments of packaged IC apparatuses that can be produced according to the method 1500 of FIG. 15. For example, each of the packaged IC apparatuses of FIGS. 20-23 can be formed from (e.g., starting with) the packaged IC apparatus shown in FIG. 19.

FIG. 20 illustrates an example packaged IC apparatus where the second layer 1710 (e.g., an oxide layer) of FIG. 19 is removed from the opening 1910 to expose the active circuitry 1760 of the die 1610.

FIG. 21 illustrates an example packaged IC apparatus where the opening 1910 is filled with one or more layers of translucent or transparent material 2110 on the second layer 1710 or oxide layer of FIG. 19. For example, surface 2120 is an inner sidewall surface of the mold compound 1810 which extends from the surface 1612 of the die and is orthogonal to the surface 1612 of the die.

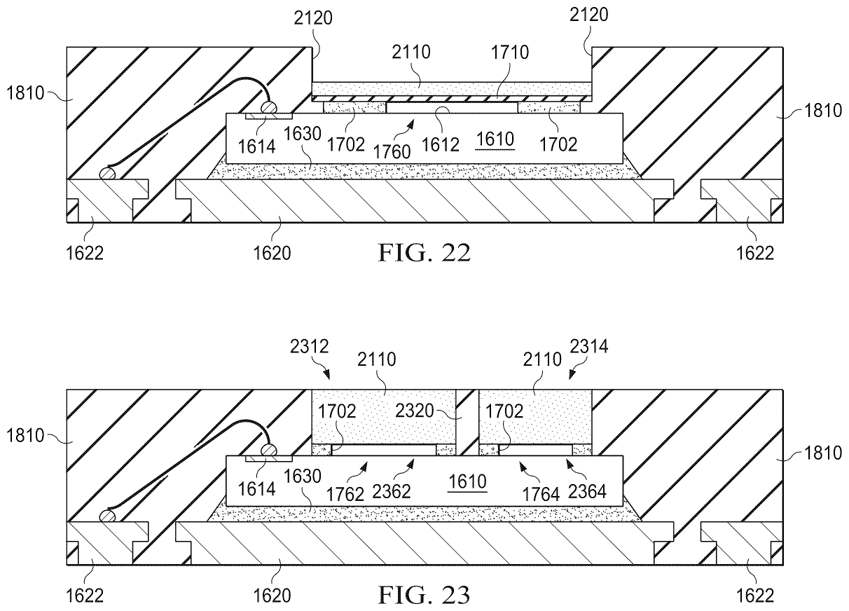

FIG. 22 illustrates an example packaged IC apparatus where the opening 1910 is partially filled with one or more layers of translucent or transparent material 2110 on the second layer 1710 or oxide layer of FIG. 19. According to a different example, the IC of FIG. 22 is fabricated by partially removing a portion of the transparent layer of material 2110 of FIG. 21.

FIG. 23 illustrates an example packaged IC apparatus where multiple openings 2312, 2314 are formed. For example, the multiple openings 2312, 2314 can be formed by removing at least a portion of the first layer 1720 from the cap 1700 of FIG. 18 and filling that portion with mold compound 1810 to form a divider 2320 between the multiple openings 2312, 2314. Thereafter, the remaining portion (e.g., 2312, 2314) of the cap 1700 is removed and those openings can be filled or partially filled with one or more layers transparent or translucent material 2110 to form the multiple openings 2312, 2314. The IC of FIG. 23 is beneficial for exposing multiple active circuitries (e.g., a first active circuitry 1762, a second active circuitry 1764) or sensors on the die 1610 at respective first and second areas 2362, 2364 near the surface of the die, spaced inwardly from the spacers 1702.

In this description, the term “couple” can cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In this description, a device that is “configured to” perform a task or function can be configured (e.g., programmed and/or hardwired) at a time of manufacturing by a manufacturer to perform the function and/or can be configurable (or reconfigurable) by a user after manufacturing to perform the function and/or other additional or alternative functions. The configuring can be through firmware and/or software programming of the device, through a construction and/or layout of hardware components and interconnections of the device, or a combination thereof. Furthermore, a circuit or device that is described herein as including certain components can instead be configured to couple to those components to form the described circuitry or device. For example, a structure described herein as including one or more semiconductor elements (such as transistors), one or more passive elements (such as resistors, capacitors, and/or inductors), and/or one or more sources (such as voltage and/or current sources) can instead include only the semiconductor elements within a single physical device (e.g., a semiconductor die and/or integrated circuit (IC) package) and can be configured to couple to at least some of the passive elements and/or the sources to form the described structure, either at a time of manufacture or after a time of manufacture, such as by an end-user and/or a third-party.

The phrase “based on” means “based at least in part on.” Therefore, if X is based on Y, X can be a function of Y and any number of other factors.

Modifications are possible in the described embodiments, and other embodiments are possible, within the scope of the claims.

What is claimed is:

1. A method, comprising:
forming a mask layer on a first surface of a first wafer, wherein:
the first wafer has a second surface that is opposite the first surface,
the first wafer comprises a substrate layer and a second layer between first and second surfaces thereof,
the second surface of the first wafer is bonded to a surface of a second wafer by a die attach material that spaces the second surface of the first wafer apart from the surface of the second wafer, and
the second wafer comprises a plurality of dies distributed across the surface of the second wafer, each die including active circuitry on the at locations on the surface of the second wafer spaced from the die attach material;
forming a pattern in the mask layer to expose areas on the first surface of the first wafer through the patterned mask layer, wherein the exposed areas overlie respective active circuitry of the second wafer; and
removing the substrate layer from the first wafer from the exposed areas of the first surface of the first wafer to provide openings that overlie respective active circuitry.

2. The method of claim 1, wherein the first wafer further comprises a second layer between the substrate layer and the second surface thereof, and the method further comprises removing the second layer from the first wafer from the exposed areas to expose the respective active circuitry.

3. The method of claim 2, wherein removing the second layer from the first wafer is performed by a waterjet.

4. The method of claim 1, wherein the first wafer further comprises a second layer between the substrate layer and the second surface thereof,
the substrate layer of the first wafer comprises silicon,
the second layer of the first wafer comprises an oxide, and
the die attach material comprises an epoxy.

5. The method of claim 1, comprising packaging the first wafer and second wafer with mold compound using film assisted molding (FAM) by loading the first wafer and the second wafer into a mold chase, clamping the mold chase, and filling cavities within the mold chase with the mold compound.

6. A method, comprising:
providing a cap overlying an area on a first surface of a die, in which the cap comprises a first layer over a second layer between opposing first and second surfaces, the second surface of the cap is bonded to and spaced apart from the first surface of the die by a spacer, and an area of the die spaced inwardly from the spacer includes active circuitry;
applying mold compound to cover the die and at least a portion of the cap such that the first surface of the cap is uncovered; and
removing at least a portion of the first layer from the cap that overlies the area of the die to form an opening.

7. The method of claim 6, further comprising removing at least a portion of the second layer from the cap overlying the area of the die.

8. The method of claim 6, further comprising providing a translucent or transparent layer of material in the opening.

9. The method of claim 8, further comprising removing at least a portion of the translucent or transparent layer of material.

10. The method of claim 6, wherein removing at least the portion of the first layer from the cap further comprises forming first and second openings in the cap overlying respective first and second areas of the die, in which each of the first and second areas of the die contain respective first and second active circuitry.

11. An apparatus, comprising:
a first structure comprising a substrate layer on an oxide layer, the first structure having a first surface that is opposite a second surface;
a second structure bonded to the second surface of the first structure by die attach material that spaces the second surface of the first structure from a surface of the second structure, wherein the second structure includes an active circuitry at the surface of the second structure at a location spaced inwardly from the die attach material; and
an opening in the first structure to expose the oxide layer of the first structure or to expose the active circuitry, the opening extends from the first surface of the first structure through the substrate layer and is aligned with an area at the surface of the second structure occupied by the active circuitry.

12. The apparatus of claim 11, wherein the substrate layer of the first structure comprises silicon and the die attach material comprises an epoxy.

13. The apparatus of claim 11, wherein the opening has a sidewall surface extending between first and second surfaces of the first structure orthogonal to the surface of the die and the first and second surfaces of the first structure.

14. The apparatus of claim 13, wherein the sidewall of the opening in the first structure surrounds and exposes the active circuitry.

15. An apparatus, comprising:
a die comprising active circuitry positioned at an area at or near a surface of the die;
a spacer on the surface of the die, the area containing the active circuitry being spaced inwardly from the spacer;
mold compound covering at least a portion of the die, wherein:
the active circuitry or a translucent or transparent layer of material on the active circuitry is uncovered; and
an inner sidewall surface of the mold compound extending from the surface of the die is orthogonal to the surface of the die.

16. The apparatus of claim 15, wherein the spacer comprises an epoxy and the translucent or transparent layer of material comprises an oxide.

17. The apparatus of claim 15, further comprising translucent or transparent mold compound on the translucent or transparent layer of material.

18. The apparatus of claim 15, further comprising a leadframe, the die mounted on the leadframe.

19. The apparatus of claim 15, wherein the active circuitry is a first active circuitry, the apparatus further comprising a second active circuitry positioned at a second area of the die spaced inwardly from the spacer. 20 The apparatus of claim 19, wherein the mold compound covers at least a portion of the die such that the second active circuitry or the translucent or transparent layer of material on the second active circuitry is uncovered.

21. The apparatus of claim 15, wherein an inner sidewall surface associated with the unencapsulated portion extending from the surface of the die or the spacer is orthogonal to the surface of the die.
